(19) United States
(12) Patent Application Publication
(10) Pub. No.: US 2025/0317065 A1
(43) Pub. Date: Oct. 9, 2025

(54) CONTROL CIRCUIT AND METHOD OF POWER SUPPLY SYSTEM

(71) Applicant: Delta Electronics (Thailand) Public Company Limited, Samutprakarn (TH)

(72) Inventors: Phichej Cheevanantachai, Samutprakarn (TH); Pannaphat Sribang, Samutprakarn (TH); Weerapus Pakakasama, Samutprakarn (TH)

(21) Appl. No.: 19/097,504

(22) Filed: Apr. 1, 2025

Related U.S. Application Data
(60) Provisional application No. 63/573,650, filed on Apr. 3, 2024.

(51) Int. Cl. H02M 3/335; H02M 7/5395

(52) U.S. Cl. CPC H02M 3/33523; H02M 3/33515; H02M 7/5395

(57) ABSTRACT

A control circuit and method of a power supply system is provided. The power supply system includes an AC/DC circuit and an isolated DC/DC circuit. The control circuit includes primary and secondary control units and a digital opto-isolation coupler. The primary control unit receives and converts operational parameter signals of the AC/DC circuit into one PWM signal. The secondary control unit is isolated from the primary control unit. The digital opto-isolation coupler transmits the PWM signal from the primary control unit to the secondary control unit in optical form. The secondary control unit decodes the PWM signal into digital status signals, corresponding to the operational parameter signals respectively, and provides the isolated DC/DC circuit with control signals according to the digital status signals.

### CROSS-REFERENC TO RELATED APPLICATION

This application claims the benefit of U.S. Provisional Application No. 63/573,650 filed on Apr. 3, 2024 and entitled “MULTI-DIGIT MODULATION CODING TECHNIQUE USING SINGLE OPTO-ISOLATOR AND ITS APPLICATION IN POWER MODULE REAL TIME MONITORING”. The entire contents of the above-mentioned patent application are incorporated herein by reference for all purposes.

### FIELD OF THE INVENTION

The present disclosure relates to a control circuit and method of a power supply system, and more particularly to a control circuit and method of a power supply system with voltage isolation.

### BACKGROUND OF THE INVENTION

Conventionally, multiple opto-isolators are required in power supply systems in order to transmit multiple signals between isolated primary and secondary circuits. For example, the power supply system may include an AC/DC circuit and an isolated DC/DC circuit. The primary control unit may send status signals of the AC/DC circuit to the secondary control unit through opto-isolators, and thus the secondary control unit can adjust PWM signals for controlling the isolated DC/DC circuit according to the status signals of the AC/DC circuit. In specific, the primary control unit converts the analog status signal to a two-level digital signal, the digital signal is from the primary control unit is transmitted to the secondary control unit through the opto-isolator, and the secondary control unit decodes the digital signal to obtain the analog status signal.

Typically, each opto-isolator can only transmit one-bit information, i.e., one two-level digital signal. Accordingly, the more information needs to be transmitted between the primary control unit and the secondary control unit, the more opto-isolators need to be used. Therefore, the cost and occupied space are increased.

Therefore, there is a need of providing a control circuit and method of a power supply system in order to overcome the drawbacks of the conventional technologies.

### SUMMARY OF THE INVENTION

The present disclosure provides a control circuit and method of a power supply system. In the control circuit and method, multiple signals may be converted into a single PWM signal carrying multi-bit information, and thus the multi-bit information carried by the PWM signal can be transmitted from the primary side to the secondary side, isolated with the primary side, through the digital opto-isolation coupler. Thereby, the number of the opto-isolators need to be used is decreased, and thus the cost and occupied space are reduced.

In accordance with an aspect of the present disclosure, a control circuit of a power supply system is provided. The power supply system includes an AC/DC circuit and an isolated DC/DC circuit connected to the AC/DC circuit. The control circuit includes a primary control unit, a secondary control unit and a digital opto-isolation coupler. The primary control unit is electrically connected to the AC/DC circuit, and is configured to receive and convert operational parameter signals of the AC/DC circuit into one PWM signal. The secondary control unit is isolated from the primary control unit and electrically connected to the isolated DC/DC circuit, and is configured to provide control signals to the isolated DC/DC circuit. The digital opto-isolation coupler is configured to provide isolated communication between the primary control unit and the secondary control unit and transmit the PWM signal from the primary control unit to the secondary control unit in optical form. The secondary control unit is configured to decode the PWM signal into digital status signals corresponding to the operational parameter signals respectively, and generate the control signals according to the digital status signals.

In accordance with an aspect of the present disclosure, a control method of a power supply system is provided. The power supply system includes an AC/DC circuit and an isolated DC/DC circuit connected to the AC/DC circuit. The control method includes steps of: (a) receiving operational parameter signals of the AC/DC circuit by a primary control unit; (b) converting the operational parameter signals into one PWM signal by the primary control unit; (c) transmitting the PWM signal from the primary control unit to a secondary control unit through a digital opto-isolation coupler in optical form, wherein the primary control unit and the secondary control unit are isolated, and the digital opto-isolation coupler is configured to provide isolated communication between the primary control unit and the secondary control unit; (d) decoding the PWM signal into digital status signals, corresponding to the operational parameter signals respectively, by the secondary control unit; and (e) providing the isolated DC/DC circuit with control signals according to the digital status signals by the secondary control unit.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic block diagram illustrating a power supply system and a control circuit thereof according to an embodiment of the present disclosure;

FIG. 2 is a schematic block diagram illustrating an implementation of the power supply system and control circuit of FIG. 1;

FIG. 3 schematically shows the multi-digit modulation encoding-decoding technique adopted by the control unit;

FIG. 4 schematically shows the relation between the operational parameter signals and the corresponding digital status signals based on the multi-digit modulation encoding-decoding technique;

FIG. 5 schematically shows an implementation of the digital opto-isolation coupler of the present disclosure; and

FIG. 6 is a schematic flow chart illustrating a control method of a power supply system according to an embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

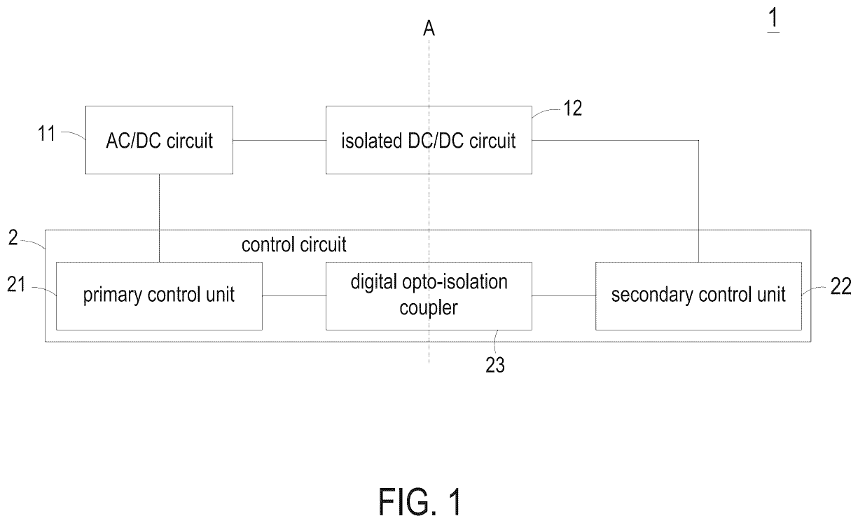

Please refer to FIG. 1. FIG. 1 is a schematic block diagram illustrating a power supply system and a control circuit thereof according to an embodiment of the present disclosure. In FIG. 1, the line A is used to separate a primary side and a secondary side isolated with each other. Specifically, the left side of line A is the primary side, and the right side of line A is the secondary side. As shown in FIG. 1, the power supply system 1 includes an AC/DC circuit 11, an isolated DC/DC circuit 12, and a control circuit 2. The AC/DC circuit 11 is located at the primary side. The isolated DC/DC circuit 12 is connected to the AC/DC circuit 11. In specific, the isolated DC/DC circuit 12 includes a primary part located at the primary side and a secondary part located at the secondary side, and the primary part of the isolated DC/DC circuit 12 is connected to the AC/DC circuit 11. For instance, the isolated DC/DC circuit 12 may include an isolated transformer configured to transfer power between the primary and secondary parts of the isolated DC/DC circuit 12.

The control circuit 2 includes a primary control unit 21, a secondary control unit 22 and a digital opto-isolation coupler 23. The primary control unit 21 is electrically connected to the AC/DC circuit 11 and is located at the primary side. The primary control unit 21 is configured to receive operational parameter signals (e.g., sensing signals of input and output voltages, an input current and an input power of the AC/DC circuit 11), which reflect the operation status of the AC/DC circuit 11, and convert the operational parameter signals into a single PWM (pulse width modulation) signal. In an embodiment, the operational parameter signals may be analog signals. The secondary control unit 22 is located at the secondary side and is isolated from the primary control unit 21. Further, the secondary control unit 22 is electrically connected to the isolated DC/DC circuit 12 and is configured to provide control signals to the isolated DC/DC circuit 12. For example, the primary control unit 21 and the secondary control unit 22 may be implemented by microcontroller units or microprocessor units, but not limited thereto.

It is noted that the primary control unit 21 and the secondary control unit 22 are respectively located at the primary side and the secondary side and are isolated from each other. The digital opto-isolation coupler 23 is configured to provide isolated communication between the primary control unit 21 and the secondary control unit 22 in optical form. In an embodiment, the digital opto-isolation coupler 23 is configured to transmit the PWM signal from the primary control unit 21 to the secondary control unit 22 in optical form. The secondary control unit 22 is configured to decode the PWM signal into digital status signals, corresponding to the operational parameter signals respectively, and control the isolated DC/DC circuit 12 according to the digital status signals. In particular, each digital status signal reflects the status of the corresponding operational parameter signals, thus the secondary control unit 22 obtains the statuses of the operational parameter signals through the digital status signals and generates the control signals accordingly. In an embodiment, the digital opto-isolation coupler 23 may include a plurality of opto-isolators, each of which includes a pair of input and output ports, and the PWM signal is transmitted by one of the plurality of opto-isolators. Specifically, in each opto-isolator, the input port is located at one of the primary and secondary sides, and the output port is located at the other one of the primary and secondary sides. For example, the opto-isolator may include a light-emitting diode and a photo detector with electrical isolation, but not exclusively.

To ensure proper control and desired output power of the power supply system 1, it is necessary to control the operations of the AC/DC circuit 11 and the isolated DC/DC circuit 12 with reference to operation status of each other. Therefore, the primary control unit 21 and the secondary control unit 22 would need to exchange information with each other so as to achieve desired control. Since the AC/DC circuit 11 and the isolated DC/DC circuit 12 are isolated, and the transmission pairs of the digital opto-isolation coupler 23 are limited, encoding information of multiple operational parameter signals into one PWM signal for transmission could both save hardware cost and improve transmission efficiency.

The operational parameter signals may indicate changes of different units or nodes of the AC/DC circuit 11 and/or isolated DC/DC circuit 12, for example input voltage/current or output voltage/current. The primary control unit 21 may receive such operational parameter signals relevant to the control of the isolated DC/DC circuit 12 or even the power supply system 1 from the AC/DC circuit 11 and transmit them to the secondary control unit 22 via the digital opto-isolation coupler 23. In order to combine information of multiple operational parameter signals into a single PWM signal, each operational parameter signal is digitized into one-bit representation. The bit value 0 indicates a first status of the corresponding unit or node that the operational parameter signal is sensed from, and the bit value 1 indicates a second status accordingly. Depending on the number of operational parameter signals to be transmitted from one side to the other side, the number, or say length, of bits to be encoded into a single PWM signal is accordingly set.

Coding or modulation of the multiple bits are performed by adjusting frequency or duty cycle of the PWM signal. For example, in the implementation of using only frequency modulation, different bit value combinations may correspond to different frequency values of the PWM signal, and the duty cycle of the PWM signal may be fixed. Taking the example of 2-bit modulation, as shown in Table 1, the binary value is formed by two bits (i.e., values of two digital status signals So1 and So2), each indicates the status of the corresponding operational parameter signal. Binary value 00 corresponds to frequency F1, binary value 01 corresponds to frequency F2, binary value 10 corresponds to frequency F3 and binary value 11 corresponds to frequency F4. The frequency values F1-F4 may be determined by predefined rules, for example in ascending order by a fixed offset, such as from 1 kHz to 4 kHz with an offset of 1 kHz.

TABLE 1

| | |
|---|---|
| Binary value | Frequency of the |

| So1 | So2 | PWM signal |
|---|---|---|
| 0 | 0 | F1 |
| 0 | 1 | F2 |
| 1 | 0 | F3 |
| 1 | 1 | F4 |

Yet in the implementation of using duty cycle modulation, the frequency of the PWM signal is fixed, and different bit values are encoded with different duty cycle of the PWM signal. For example, as shown in Table 2, the frequency is set to 1 kHz, and the binary values of 00, 01, 10 and 11 respectively correspond to the duty cycles of 20%, 40%, 60% and 80%.

TABLE 2

| | |
|---|---|
| Binary value | Duty cycle of |

| So1 | So2 | the PWM signal |
|---|---|---|
| 0 | 0 | 20% |
| 0 | 1 | 40% |
| 1 | 0 | 60% |
| 1 | 1 | 80% |

In another implementation using both frequency and duty cycle modulation, frequency changes may correspond to some bits and duty cycle changes may correspond to other bits. Taking the example of 4-bit modulation, as shown in Table 3, the binary value is formed by four bits (i.e., values of four digital status signals So1, So2, So3 and So4), each indicates the status of the corresponding operational parameter signal. The first two bits (i.e., So1 and So2) of the binary value of 00, 01, 10 and 11 respectively correspond to the frequencies of the PWM signal of F1, F2, F3 and F4. The last two bits (i.e., So3 and So4) of the binary value of 00, 01, 10 and 11 respectively correspond to the duty cycles of the PWM signal of 25%, 50%, 75% and 90%. In other alternative implementations, both the frequency and the duty cycle may change along with the bit values.

TABLE 3

| | |
|---|---|
| Binary value | PWM signal |

| So1 | So2 | So3 | So4 | Frequency | Duty cycle |
|---|---|---|---|---|---|
| 0 | 0 | 0 | 0 | F1 | 25% |
| 0 | 0 | 0 | 1 | F1 | 50% |
| 0 | 0 | 1 | 0 | F1 | 75% |
| 0 | 0 | 1 | 1 | F1 | 90% |
| 0 | 1 | 0 | 0 | F2 | 25% |
| 0 | 1 | 0 | 1 | F2 | 50% |
| 0 | 1 | 1 | 0 | F2 | 75% |
| 0 | 1 | 1 | 1 | F2 | 90% |
| 1 | 0 | 0 | 0 | F3 | 25% |
| 1 | 0 | 0 | 1 | F3 | 50% |
| 1 | 0 | 1 | 0 | F3 | 75% |
| 1 | 0 | 1 | 1 | F3 | 90% |
| 1 | 0 | 0 | 0 | F4 | 25% |
| 1 | 0 | 0 | 1 | F4 | 50% |
| 1 | 0 | 1 | 0 | F4 | 75% |
| 1 | 0 | 1 | 1 | F4 | 90% |

Conversely, upon receiving the PWM signal, the secondary control unit 22 or the primary control unit 21 may decode the PWM signal to obtain the operational parameter information. For example, for the duty cycle modulation shown in Table 2, the secondary control unit 22 may decode a PWM signal of frequency 1 kHz and duty cycle pattern (20%, 20%, 60%, 80%) to binary values (00, 00, 10, 11). Correspondingly, the secondary control unit 22 may interpret the binary values (00, 00, 10, 11) to obtain operation status of components or nodes corresponding to the two bits of the binary value. In this example, it can be known that the status of the first bit is changed first and later the status of the second bit also changed. Both the primary control unit 21 and the secondary control unit 23 may maintain the coding/modulation rules or mapping policy so that the PWM signal can be properly encoded and decoded automatically without transmitting further signals for interpreting the PWM signal.

By using the encoding or modulation scheme of as described above, the present disclosure may achieve transmission of multiple operational parameter signals with a single PWM signal between two isolated circuits in a power supply system, such as FIG. 1. One with ordinary skill in the art may understand that the present disclosure may be extended to transmit more than two operational parameter signals using a PWM signal encoded by more than two bits. Depending on the control purpose or control scheme, any number of necessary operational parameter signals may be encoded by the primary control unit 21 or the secondary control unit 22, and transmitted to the other side through the digital opto-isolation coupler 23.

In addition to the frequency and/or duty cycle configuration, sampling rate and pattern interval of the PWM signal may also be set to ensure precise and timely information transmission and coding. For instance, the operational parameter signals may be sampled at a predefined rate according to the operating frequency of the AC/DC circuit or DC/DC circuit. The sampling rate may be increased when the power supply system is running at a higher frequency. And the minimum width of each bit value pattern may be set to a predefined time period so that minor noise of the PWM signal would not cause trouble to the reception or demodulation of the PWM signal.

Furthermore, in the case that the power supply system 1 may operate in different conversion modes and control policies under different modes may change accordingly, the PWM signal may be encoded with a special pattern lasting for a predetermined time period so as to signify mode switch. Also, the PWM signal coding scheme may be changed depending on the conversion mode. For example, the bit length, i.e., number of bits, may stay the same, but the operational parameter signals represented by the bits are changed. In another example, the coding scheme may also be changed. For example, the coding scheme may be based on frequency in a first mode and based on both frequency and duty cycle in a second mode. In other implementations, the bit length and bit pattern may both be changed.

Consequently, multiple signals (i.e., operational parameter signals) may be converted into a single PWM signal carrying multi-bit information, and thus the multi-bit information carried by the PWM signal can be transmitted between the primary side and the secondary side, isolated with each other, through one pair of input and output ports (i.e., one opto-isolator) of the digital opto-isolation coupler 23. Thereby, the number of the opto-isolators need to be used is decreased, and thus the cost and occupied space are reduced.

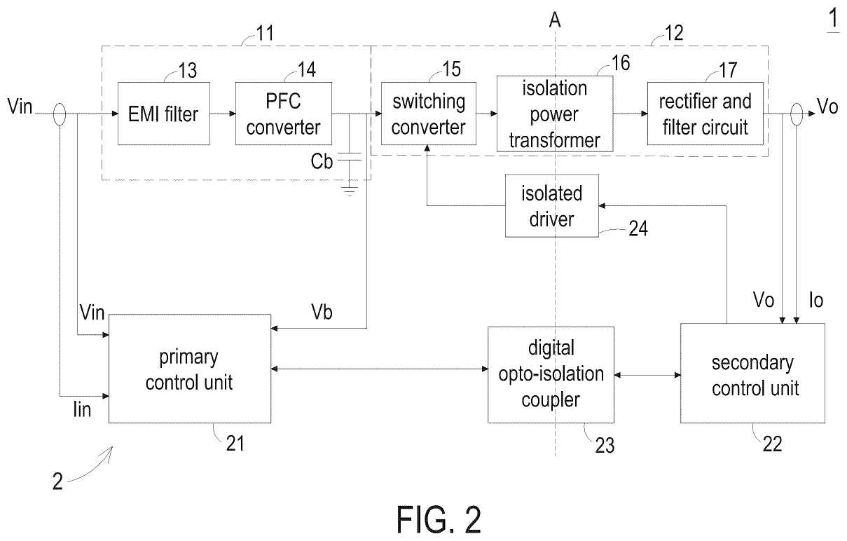

Please refer to FIG. 2. FIG. 2 is a schematic block diagram illustrating an exemplary implementation of the power supply system 1 and control circuit 2 of FIG. 1. The component parts and elements corresponding to those of FIG. 1 are designated by identical numeral references, and detailed descriptions thereof are omitted herein. As shown in FIG. 2, in the power supply system 1 of this embodiment, the AC/DC circuit 11 includes an EMI (electromagnetic interference) filter 13, a PFC (power factor correction) converter 14 and a bulk capacitor Cb. And the isolated DC/DC circuit 12 includes a switching converter 15, an isolation power transformer 16 and a rectifier and filter circuit 17. The EMI filter 13 is configured to receive an input voltage Vin and perform EMI filtering. The PFC converter 14 is electrically connected to the EMI filter 13 and is configured to perform power factor correction and provide a bulk voltage Vb (i.e., the voltage across the bulk capacitor Cb) to the isolated DC/DC circuit 12. The bulk voltage Vb may also be regarded as the output voltage of the AC/DC circuit 11. In the AC/DC circuit 11, the EMI filter 13, the PFC converter 14 and the bulk capacitor Cb are all located at the primary side. In the isolated DC/DC circuit 12, the switching converter 15 is located at the primary side, the rectifier and filter circuit 17 is located at the secondary side, and the isolated power transformer 16 may be formed by a primary winding located at the primary side and a secondary winding located at the secondary side. The switching converter 15 is electrically connected to the PFC converter 14 and is configured to receive and convert the bulk voltage Vb into an AC voltage. The isolation power transformer 16 is electrically connected to the switching converter 15 and is configured to transmit the AC voltage from the primary side to the secondary side. The rectifier and filter circuit 17 is electrically connected to the isolation power transformer 16 and is configured to perform rectification and filtering on the AC voltage to generate an output voltage Vo of the isolated DC/DC circuit 12.

In an embodiment, for controlling the operation of the power supply system 1, the primary control unit 21 may sample the input voltage Vin and an input current Iin received by the AC/DC circuit 11 and the bulk voltage Vb outputted by the AC/DC circuit 11, and the secondary control unit 22 may sample the output voltage Vo and an output current Io outputted by the isolated DC/DC circuit 12. In addition, in an embodiment, the control circuit 2 further includes an isolated driver 24. The isolated driver 24 is coupled between the secondary control unit 22 and the switching converter 15 of the isolated DC/DC circuit 12. The isolated driver 24 is configured to receive the control signals generated by the secondary control unit 22 and provide a driving signal for driving switches of the switching converter 15 according to the control signal. For example, the isolation stage of the isolated driver 24 may be implemented by opto-coupler, isolated transformer, capacitive isolation or magnetic isolation.

In the present disclosure, the control unit 2 adopts multi-digit modulation encoding-decoding technique to transmit multi-bit information of multiple signals from the primary side to the secondary side through a single PWM signal.

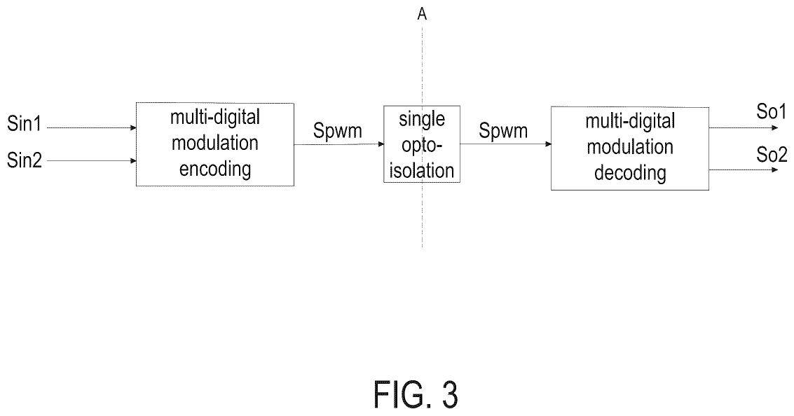

Please refer to FIG. 3 in conjunction with FIG. 2. FIG. 3 schematically shows the multi-digit modulation encoding-decoding technique adopted by the primary control unit 21 and secondary control unit 23. As shown in FIG. 3, the primary control unit 21 performs the multi-digit modulation encoding to convert operational parameter signals of the AC/DC circuit 11 into a single PWM signal Spwm. The single PWM signal Spwm from the primary control unit 21 is transmitted through a single opto-isolator of the digital opto-isolation coupler 23 to the secondary control unit 22. The secondary control unit 22 receives the PWM signal Spwm and performs the multi-digit modulation decoding to decode the PWM signal Spwm into digital status signals corresponding to the operational parameter signals respectively. In an embodiment, the PWM signal Spwm may be provided with different frequencies or duty cycles or different combinations of frequency and duty cycle to represent different statuses of the operational parameter signals. For instance, the primary control unit 21 may determine the status of the operational parameter signals by comparing each operational parameter signal with corresponding one or more threshold values. Accordingly, the secondary control unit 22 decodes the PWM signal Spwm into digital status signals according to the frequency and duty cycle of the PWM signal Spwm.

While performing the multi-digit modulation encoding, the operational parameter signals may be converted into digital signals, and then the digital signals are converted into the single PWM signal Spwm. Alternatively, the operational parameter signals may be directly converted into the single PWM signal Spwm. In addition, the relation between the operational parameter signal and the corresponding digital status signal may be determined according to the specific type of the operational parameter signal. For example, the digital status signal is at high level when the corresponding operational parameter signal is within a first range, and the digital status signal is at low level when the corresponding operational parameter signal is within a second range.

It is noted that the number of operational parameter signals is not limited. FIG. 3 schematically shows two operational parameter signals Sin1 and Sin2 and two corresponding digital status signals So1 and So2 as an example.

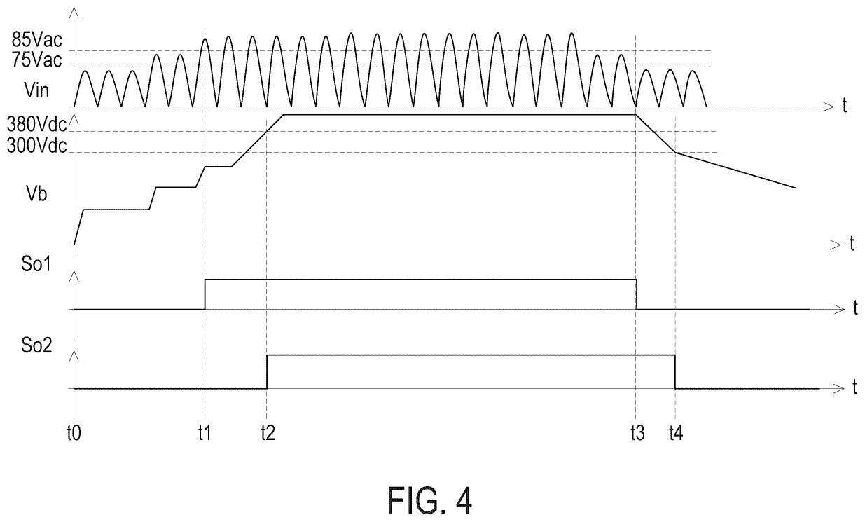

Please refer to FIG. 4 in conjunction with FIG. 2 and FIG. 3. FIG. 4 schematically shows the relation between the operational parameter signals and the corresponding digital status signals based on the multi-digit modulation encoding-decoding technique. In FIG. 4, two operational parameter signals Sin1 and Sin2 are exemplified as the sensing signals of the input voltage Vin and the bulk voltage Vb, the digital status signal So1 is corresponding to the status of input voltage Vin, and the digital status signal So2 is corresponding to the status of bulk voltage Vb. For example, it is assumed that the digital status signal So1 changes from low level to high level when the RMS (root mean square) value of input voltage Vin reaches 85 Vac, the digital status signal So1 changes from high level to low level when the RMS value of input voltage Vin falls below 75 Vac, the digital status signal So2 changes from low level to high level when the bulk voltage Vb reaches 380 Vdc, the digital status signal So2 changes from high level to low level when the bulk voltage Vb falls below 300 Vdc.

Assuming modulation of the PWM signal Spwm is based on frequency, as shown in FIG. 4, at time t0, the input voltage Vin starts to apply, and the bulk voltage Vb starts to increase. During the time period from time t0 to t1, the RMS value of input voltage Vin is lower than 85 Vac, and the bulk voltage Vb is lower than 380 Vdc. During this time period, the PFC converter 14 is not turned on. Correspondingly, the digital status signals So1 and So2 are both at low level, and the PWM signal Spwm is set at a first frequency. At time t1, the RMS value of input voltage Vin reaches 85 Vac. During the time period from time t1 to t2, the RMS value of input voltage Vin is higher than 85 Vac, and the bulk voltage Vb is still lower than 380 Vdc. During this time period, the PFC converter 14 is turned on and starts to boost for reaching 400 Vdc. Correspondingly, the digital status signal So1 is at high level, and the digital status signal So2 is still at low level, thus the PWM signal Spwm is set at a second frequency. At time t2, the bulk voltage Vb reaches 380 Vdc. During the time period from time t2 to t3, the RMS value of input voltage Vin is higher than 75 Vac, and the bulk voltage Vb is higher than 300 Vdc and is constantly maintained at 400 Vdc after reaching 400 Vdc. Correspondingly, the digital status signals So1 and So2 are both at high level, and the PWM signal Spwm is at a third frequency. At time t3, the RMS value of input voltage Vin falls below 75 Vac. During the time period from time t3 to t4, the RMS value of input voltage Vin is lower than 75 Vac, and the bulk voltage Vb is still higher than 300 Vdc. During this time period, since the input voltage Vin drops below 75 Vac, the PFC converter 14 is turned off, and the bulk voltage Vb decreases. Correspondingly, the digital status signal So1 is at low level, and the digital status signal So2 is still at high level, thus the PWM signal Spwm is set at a fourth frequency. At time t4, the bulk voltage Vb falls below 300 Vdc. After time t4, the RMS value of input voltage Vin is lower than 75 Vac, and the bulk voltage Vb is lower than 300 Vdc. Correspondingly, the status of input voltage Vin and bulk voltage Vb is the same as that during the time period from time to to t1 in which the digital status signals So1 and So2 are both at low level, thus the PWM signal Spwm is set at the first frequency.

In this embodiment, the PWM signal Spwm is provided with different frequencies to represent different statuses of input voltage Vin and bulk voltage Vb. However, the present disclosure is not limited thereto. For example, in another embodiment, the PWM signal Spwm may be provided with different duty cycles to represent different statuses of input voltage Vin and bulk voltage Vb. In further another embodiment, the PWM signal Spwm may be provided with different combinations of frequency and duty cycle to represent different statuses of input voltage Vin and bulk voltage Vb.

In addition, it is noted that the encoding and decoding manner exemplified above can also be extended to apply to three or more operational parameter signals.

Moreover, the above descriptions focus on transmitting signal from the primary side to the secondary side. While in some embodiments, please refer to FIG. 2 again, the digital opto-isolation coupler 23 may be bidirectional. In particular, in addition to the signal transmission from the primary control unit 21 to the secondary control unit 22, the digital opto-isolation coupler 23 can also transmit the signal from the secondary control unit 22 to the primary control unit 21. For example, the secondary control unit 22 may receive the operational parameter signals (e.g., the sensing signals of output voltage Vo and output current Io) of the isolated DC/DC circuit 12 at the secondary side and convert them into a single PWM signal, the PWM signal is transmitted to the primary control unit 21 through the digital opto-isolation coupler 23, and the primary control unit 21 decodes the PWM signal into digital signals corresponding to the operational parameter signals of the isolated DC/DC circuit 12. Accordingly, multi-bit information can be carried by a single PWM signal and transmitted between the isolated primary and secondary sides. In addition, in an embodiment, the digital opto-isolation coupler 23 is also used for data transmission between the primary control unit 21 and the secondary control unit 22 based on other transmission protocol, for example UART (Universal Asynchronous Receiver-Transmitter) communication protocol. In particular, the digital opto-isolation coupler 23 may transmit the data from the primary control unit 21 to the secondary control unit 22 and transmit the data from the secondary control unit 22 to the primary control unit 21.

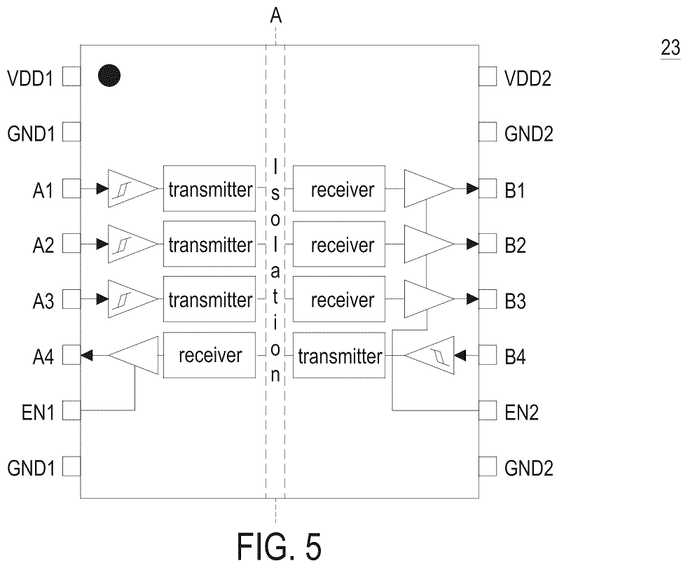

Please refer to FIG. 5. FIG. 5 schematically shows an implementation of the digital opto-isolation coupler 23 of the present disclosure. In FIG. 5, pins VDD1 and VDD2 are configured for power supply, pins GND1 and GND2 are configured for grounding, pins EN1 and EN2 are configured for enabling, and pins A1, A2, A3, A4, B1, B2, B3 and B4 are configured for digital input or output. In this embodiment, as shown in FIG. 5, the digital opto-isolation coupler 23 includes four opto-isolators, each including a transmitter and a receiver. The first opto-isolator includes the pin A1 at the primary side and the pin B1 at the secondary side, and the pins A1 and B1 serve as input and output pins respectively. The second opto-isolator includes the pin A2 at the primary side and the pin B2 at the secondary side, and the pins A2 and B2 serve as input and output pins respectively. The third opto-isolator includes the pin A3 at the primary side and the pin B3 at the secondary side, and the pins A3 and B3 serve as input and output pins respectively. The fourth opto-isolator includes the pin A4 at the primary side and the pin B4 at the secondary side, and the pins B4 and A4 serve as input and output pins respectively.

For example, the third opto-isolator transmits the communication data from the primary control unit 21 to the secondary control unit 22, and the fourth opto-isolator transmits the communication data from the secondary control unit 22 to the primary control unit 21. In the prior art, if the digital opto-isolation coupler 23 transmits the information of the input voltage Vin and bulk voltage Vb from the primary side to the secondary side, two opto-isolators (e.g., the first and second opto-isolators) need to be used for transmission because each opto-isolator can only transmit one-bit information. While in the present disclosure, through the multi-digit modulation encoding-decoding technique described above, the information of the input voltage Vin and bulk voltage Vb is combined into a single PWM signal, and only one opto-isolator (e.g., the first opto-isolator) is required to transmit the single PWM signal carrying multi-bit information (i.e., optical signal carrying multi-bit information). Therefore, the unused opto-isolator (e.g., the second opto-isolator) may be recycled or redefined to transfer additional information. Further, the input and output pins of the unused opto-isolator may be redefined to change transmission direction, thereby allowing more flexible bidirectional transmission.

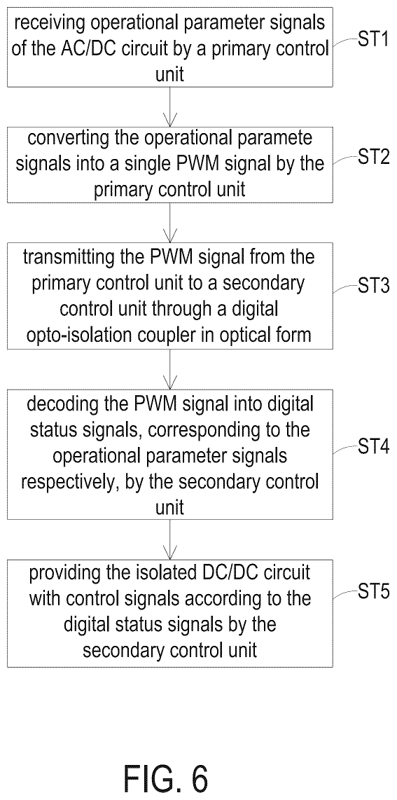

Please refer to FIG. 6 in conjunction with FIG. 1. FIG. 6 is a schematic flow chart illustrating a control method of the power supply system 1 according to an embodiment of the present disclosure. The control method is applicable for the power supply system 1 of FIG. 1 and FIG. 2. As shown in FIG. 6, the control method includes steps ST1, ST2, ST3, ST4 and ST5. In step ST1, a primary control unit 21 is utilized to receive operational parameters of the AC/DC circuit 11. In step ST2, the primary control unit 21 is utilized to convert the operational parameter signals into a single PWM signal. In step ST3, a digital opto-isolation coupler 23 is utilized to transmit the PWM signal from the primary control unit 21 to a secondary control unit 22 in optical form. In step ST4, the secondary control unit 22 is utilized to decode the PWM signal into digital status signals corresponding to the operational parameter signals respectively. In step ST5, the secondary control unit 22 is utilized to provide the isolated DC/DC circuit 12 with control signals according to the digital status signals.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A control circuit of a power supply system comprising an AC/DC circuit and an isolated DC/DC circuit connected to the AC/DC circuit, the control circuit comprising:
a primary control unit, electrically connected to the AC/DC circuit, and configured to receive and convert operational parameter signals of the AC/DC circuit into one PWM (pulse width modulation) signal;
a secondary control unit, isolated from the primary control unit and electrically connected to the isolated DC/DC circuit, and configured to provide control signals to the isolated DC/DC circuit; and
a digital opto-isolation coupler, configured to provide isolated communication between the primary control unit and the secondary control unit, and transmit the PWM signal from the primary control unit to the secondary control unit in optical form;
wherein the secondary control unit is configured to decode the PWM signal into digital status signals corresponding to the operational parameter signals respectively, and generate the control signals according to the digital status signals.

2. The control circuit according to claim 1, wherein the primary control unit is configured to modulate the PWM signal with different frequencies, different duty cycles, or different combinations of frequency and duty cycle to represent different statuses of the operational parameter signals, and the secondary control unit is configured to decode the PWM signal into the digital status signals according to the frequency and the duty cycle of the PWM signal.

3. The control circuit according to claim 2, wherein the primary control unit is configured to digitize the operational parameter signals into a binary value with bits, each representing a status of a corresponding one of the operational parameter signals, and modulate the PWM signal with different frequencies, different duty cycles, or different combinations of frequency and duty cycle to represent different values of the binary value, and each of the digital status signals obtained by the secondary control unit corresponds to one of the bits of the binary value.

4. The control circuit according to claim 3, wherein the primary control unit is configured to modulate the PWM signal with different combinations of frequency and duty cycle to represent different values of the binary value, wherein the bits of the binary value comprise a first bit and a second bit, the frequency of the PWM signal represents a value of the first bit, and the duty cycle of the PWM signal represents a value of the second bit.

5. The control circuit according to claim 2, wherein the primary control unit is configured to determine the statuses of the operational parameter signals by comparing each of the operational parameter signals with corresponding one or more threshold values.

6. The control circuit according to claim 1, wherein the digital opto-isolation coupler comprises a plurality of opto-isolators, each of which is configured to transmit a two-level one-bit signal, and the PWM signal carrying multi-bit information from the primary control unit is transmitted to the secondary control unit through one of the plurality of opto-isolators.

7. The control circuit according to claim 1, wherein the primary control unit is configured to convert the operational parameter signals into digital signals and convert the digital signals into the PWM signal, or is configured to convert the operational parameter signals into the PWM signal directly.

8. The control circuit according to claim 1, wherein the control circuit further comprises an isolated driver coupled between the secondary control unit and the isolated DC/DC circuit, and the isolated driver is configured to provide driving signals for driving switches of the isolated DC/DC circuit according to the control signals generated by the secondary control unit.

9. The control circuit according to claim 1, wherein the operational parameter signals comprise at least two of an input voltage, an output voltage, an input current, an input power of the AC/DC circuit.

10. The control circuit according to claim 1, wherein the digital opto-isolation coupler is bidirectional, the secondary control unit is configured to receive and convert operational parameter signals of the isolated DC/DC circuit into another PWM signal, the digital opto-isolation coupler is configured to transmit the another PWM signal from the secondary control unit to the primary control unit, and the primary control unit is configured to decode the another PWM signal into digital signals corresponding to the operational parameter signals of the isolated DC/DC circuit.

11. The control circuit according to claim 1, wherein the digital opto-isolation coupler is further configured for data transmission between the primary control unit and the secondary control unit based on another transmission protocol.

12. A control method of a power supply system comprising an AC/DC circuit and an isolated DC/DC circuit connected to the AC/DC circuit, the control method comprising steps of:
(a) receiving operational parameter signals of the AC/DC circuit by a primary control unit;
(b) converting the operational parameter signals into one PWM (pulse width modulation) signal by the primary control unit;
(c) transmitting the PWM signal from the primary control unit to a secondary control unit through a digital opto-isolation coupler in optical form, wherein the primary control unit and the secondary control unit are isolated, and the digital opto-isolation coupler is configured to provide isolated communication between the primary control unit and the secondary control unit;
(d) decoding the PWM signal into digital status signals, corresponding to the operational parameter signals respectively, by the secondary control unit; and
(e) providing the isolated DC/DC circuit with control signals according to the digital status signals by the secondary control unit.

13. The control method according to claim 12, wherein in the step (b), the PWM signal is modulated with different frequencies, different duty cycles, or different combinations of frequency and duty cycle to represent different statuses of the operational parameter signals by the primary control unit; and in the step (d), the PWM signal is decoded into the digital status signals according to the frequency and the duty cycle of the PWM signal by the secondary control unit.

14. The control method according to claim 13, wherein in the step (b), the operational parameter signals are digitized into a binary value with bits, each representing a status of a corresponding one of the operational parameter signals, by the primary control unit, and the PWM signal is modulated with different frequencies, different duty cycles, or different combinations of frequency and duty cycle to represent different values of the binary value by the primary control unit; and in the step (d), each of the digital status signals obtained by the secondary control unit corresponds to one of the bits of the binary value.

15. The control method according to claim 14, wherein in the step (b), the PWM signal is modulated with different combinations of frequency and duty cycle to represent different values of the binary value by the primary control unit, the bits of the binary value comprise a first bit and a second bit, the frequency of the PWM signal represents a value of the first bit, and the duty cycle of the PWM signal represents a value of the second bit.

16. The control method according to claim 13, wherein in the step (b), the statuses of the operational parameter signals is determined by the primary control unit through comparing each of the operational parameter signals with corresponding one or more threshold values.

17. The control method according to claim 12, wherein the digital opto-isolation coupler comprises a plurality of opto-isolators, each of which is configured to transmit a one-bit signal, and in the step (c), the PWM signal from the primary control unit is transmitted to the secondary control unit through one of the plurality of opto-isolators.

18. The control method according to claim 12, wherein the step (b) comprises:
converting the operational parameter signals into digital signals and converting the digital signals into the PWM signal by the primary control unit; or
converting the operational parameter signals into the PWM signal directly by the primary control unit.

19. The control method according to claim 12, further comprising a step of providing a driving signal for driving switches of the isolated DC/DC circuit according to the control signals, generated by the secondary control unit, by an isolated driver.

20. The control method according to claim 12, wherein the operational parameter signals comprise at least two of an input voltage, an output voltage, an input current, an input power of the AC/DC circuit.

21. The control method according to claim 12, wherein the digital opto-isolation coupler is bidirectional, and the control method further comprises steps of:
receiving and converting operational parameter signals of the isolated DC/DC circuit into another PWM signal by the secondary control unit;
transmitting the another PWM signal from the secondary control unit to the primary control unit by the digital opto-isolation coupler; and
decoding the another PWM signal into digital signals, corresponding to the operational parameter signals of the isolated DC/DC circuit, by the primary control unit.

22. The control method according to claim 12, further comprising a step of performing data transmission between the primary control unit and the secondary control unit based on another transmission protocol by the digital opto-isolation coupler.
